(19) United States
(12) Patent Application Publication
(10) Pub. No.: US 2026/0105979 A1
(43) Pub. Date: Apr. 16, 2026

(54) MEMORY OVERCLOCKING DEVICE AND MEMORY OVERCLOCKING METHOD

(71) Applicant: GIGA-BYTE TECHNOLOGY CO., LTD., New Taipei City (TW)

(72) Inventors: Chia-Chih CHIEN, New Taipei City (TW); Quang Tuyen LE, New Taipei City (TW); Liang-Lin YAN, New Taipei City (TW); Hang Yee LI, New Taipei City (TW); Li-Te LIN, New Taipei City (TW); Yen Chu LU, New Taipei City (TW); Tse-Hsien LIAO, New Taipei City (TW); Sheng-Liang KAO, New Taipei City (TW)

(73) Assignee: GIGA-BYTE TECHNOLOGY CO., LTD., New Taipei City (TW)

(21) Appl. No.: 19/357,413

(22) Filed: Oct. 14, 2025

Related U.S. Application Data
(60) Provisional application No. 63/707,365, filed on Oct. 15, 2024.

(30) Foreign Application Priority Data
May 21, 2025 (TW) 114119034

(51) Int. Cl. G11C 29/12; G06F 1/08; G11C 5/14

(52) U.S. Cl. CPC G11C 29/12015; G06F 1/08; G11C 5/14

(57) ABSTRACT

A memory overclocking device includes a memory and a processor. The memory is configured to store a plurality of instructions and a basic input/output system. The processor is configured to execute following steps according to the plurality of instructions of the memory. The processor performs an overclocking prediction for a device under test according to an overclocking algorithm via the basic input/output system. The processor outputs an optimal overclocking result data according to the overclocking prediction via the basic input/output system. The processor outputs two or more compliance result data according to the optimal overclocking result data, the hardware data of the device under test, and the frequency threshold range data.

### CROSS REFERENCE TO RELATED APPLICATIONS

This application claims priority of TW patent application No. 114119034, filed on May 21, 2025, the entirety of which is incorporated by reference herein.

This application claims priority of U.S. Provisional Application No. 63/707,365, filed on Oct. 15, 2024, the entirety of which is incorporated by reference herein.

### BACKGROUND OF THE INVENTION

### Field of the Invention

The present invention relates to an overclocking device and overclocking method, and, in particular, it is related to a memory overclocking device and memory overclocking method.

### Description of the Related Art

Recent years have seen an explosive application of artificial intelligence (AI), and the emergence of generative AI has further heightened people's expectations and imagination for a future AI-driven world.

Moreover, the overclocking of Double Data Rate (DDR) memory to generally achieve higher operational efficiency is currently beyond the technical capabilities of ordinary users. Only professionals and enthusiasts experienced in memory overclocking have the knowledge and skill to successfully overclock DDR memory. Most users lack the necessary knowledge when attempting DDR memory overclocking, which often leads to failure. Even if successful, it may result in a system whose stability cannot be ensured.

Therefore, a device and method that facilitates the overclocking of DDR memory for ease of use is a subject urgently requiring research and development.

### BRIEF SUMMARY OF THE INVENTION

The present disclosure provides a brief summary of the invention to enable the reader to obtain a basic understanding of the disclosure. This summary does not constitute a complete overview of the disclosure, nor is it intended to indicate critical or essential components of the embodiments or to define the scope of the disclosure.

An embodiment of the present invention provides a memory overclocking device. The memory overclocking device includes a memory and a processor. The memory is configured to store a plurality of instructions and a basic input/output system. The processor is configured to execute following steps according to the plurality of instructions of the memory: performing an overclocking prediction for a device under test according to an overclocking algorithm by the basic input/output system; outputting an optimal overclocking result data according to the overclocking prediction by the basic input/output system; and outputting at least two compliance result data according to the optimal overclocking result data, a hardware data of the device under test, and a frequency threshold range data.

In one embodiment, the optimal overclocking result data comprises an optimal frequency data, a vendor data of the device under test, at least one time data of the device under test, and an optimal voltage data.

In one embodiment, the frequency threshold range data comprises 200 to 400 MHz.

In one embodiment, the processor further executes the following steps according to the plurality of instructions of the memory: determining whether the optimal overclocking result data is an optimal result according to the overclocking algorithm, an initial setting data of the device under test, and the hardware data of the device under test; and when it is determined that the optimal overclocking result data is the optimal result, tagging a recommendation symbol on the optimal overclocking result data.

In one embodiment, the processor further executes the following steps according to the plurality of instructions of the memory: determining whether the at least two compliance result data meet a product specification according to the overclocking algorithm and a hardware data of the device under test; and when it is determined that the at least two compliance result data meet the product specification, outputting the at least two compliance result data to an interface.

In one embodiment, the processor further executes the following steps according to the plurality of instructions of the memory: setting up an operation interface; displaying an initial setting data of the device under test, the hardware data of the device under test, the optimal overclocking result data, and the at least two compliance result data on operation interface; and tagging a recommendation symbol on the optimal overclocking result data according to the overclocking algorithm, an initial setting data of the device under test, and the hardware data of the device under test.

In one embodiment, the processor further executes the following steps according to the plurality of instructions of the memory: determining whether to perform an overclocking prediction training according to an initial setting data of the device under test; when it is determined to perform the overclocking prediction training, recording a result of the overclocking prediction training to the memory by the basic input/output system; and updating the overclocking algorithm with the result of the overclocking prediction training by the basic input/output system.

In one embodiment, the initial setting data comprises at least one of an updated basic input/output system data, a replacement data of the device under test, and a modified time data of the device under test.

In one embodiment, the device under test and the memory are different from each other; wherein the device under test comprises a dynamic random access memory.

In one embodiment, the memory overclocking device comprises a motherboard.

Other embodiment of the present invention provides a memory overclocking method. The memory overclocking method includes the following steps: storing a basic input/output system by a memory; performing an overclocking prediction for a device under test according to an overclocking algorithm by the basic input/output system; outputting an optimal overclocking result data according to the overclocking prediction by the basic input/output system; and outputting at least two compliance result data according to the optimal overclocking result data, a hardware data of the device under test, and a frequency threshold range data.

In one embodiment, the optimal overclocking result data comprises an optimal frequency data, a vendor data of the device under test, at least one time data of the device under test, and an optimal voltage data.

In one embodiment, the frequency threshold range data comprises 200 to 400 MHz.

In one embodiment, determining whether the optimal overclocking result data is an optimal result according to the overclocking algorithm, an initial setting data of the device under test, and the hardware data of the device under test; and when it is determined that the optimal overclocking result data is the optimal result, tagging a recommendation symbol on the optimal overclocking result data.

In one embodiment, determining whether the at least two compliance result data meet a product specification according to the overclocking algorithm and a hardware data of the device under test; and when it is determined that the at least two compliance result data meet the product specification, outputting the at least two compliance result data to an interface.

In one embodiment, setting up an operation interface; displaying an initial setting data of the device under test, the hardware data of the device under test, the optimal overclocking result data, and the at least two compliance result data on operation interface; and tagging a recommendation symbol on the optimal overclocking result data according to the overclocking algorithm, an initial setting data of the device under test, and the hardware data of the device under test.

In one embodiment, determining whether to perform an overclocking prediction training according to an initial setting data of the device under test; when it is determined to perform the overclocking prediction training, recording a result of the overclocking prediction training to the memory by the basic input/output system; and updating the overclocking algorithm with the result of the overclocking prediction training by the basic input/output system.

In one embodiment, the initial setting data comprises at least one of an updated basic input/output system data, a replacement data of the device under test, and a modified time data of the device under test.

In one embodiment, the device under test and the memory are different from each other; wherein the device under test comprises a dynamic random access memory.

In one embodiment, the memory overclocking method is executed by a motherboard.

Therefore, according to the technical content of the present disclosure, the memory overclocking device and memory overclocking method shown in the embodiment of the present disclosure can achieve stable memory overclocking through a corresponding algorithm, even without requiring the user to possess a professional technical background in Double Data Rate (DDR) memory overclocking.

After referring to the embodiments described below, those of ordinary skill in the art can readily understand the basic concept and other objectives of the present invention, as well as the technical means and modes of implementation employed in the present invention.

Other features and aspects of the present disclosure will become apparent from the following detailed description of exemplary embodiments with reference to the accompanying drawings.

### BRIEF DESCRIPTION OF THE DRAWINGS

The views of the embodiments of the present disclosure can be better understood through the following detailed description combined with the accompanying drawings. It is worth noting that, according to standard industrial practice, some features may not be drawn to scale. In fact, to facilitate clear description, the dimensions of different features may be increased or decreased, wherein:

FIG. 1 is a block diagram of a memory overclocking device according to one embodiment of the present disclosure.

FIG. 2 is a schematic diagram of a usage scenario of a memory overclocking device according to one embodiment of the present disclosure.

FIG. 3 is a schematic diagram of a usage scenario of a memory overclocking device according to one embodiment of the present disclosure.

FIG. 4 is a flowchart of steps of a memory overclocking method according to one embodiment of the present disclosure.

### DETAILED DESCRIPTION OF THE INVENTION

The following description is made for the purpose of illustrating the general principles of the invention and should not be taken in a limiting sense. The scope of the invention is best determined by reference to the appended claims.

To provide a more detailed and complete description of the present disclosure, explanatory descriptions of the embodiments and specific examples of the present invention are provided below; however, these are not the only forms for implementing or practicing the specific embodiments. The embodiments encompass features of multiple specific embodiments and the method steps and sequences for constructing and operating these specific embodiments. Other specific embodiments may also be utilized to achieve the same or equivalent functions and step sequences.

Unless otherwise defined in this specification, the meanings of scientific and technical terms used herein are the same as the meanings understood and commonly employed by those of ordinary skill in the art. Furthermore, unless inconsistent with the context, singular nouns used in this specification include the plural form of the noun, and plural nouns include the singular form of the noun.

Additionally, the terms “coupled” or “connected” as used herein may refer to direct physical or electrical contact between two or more elements, indirect physical or electrical contact between two or more elements, or interaction or operation between two or more elements. In some embodiments of the present disclosure, terms related to joining and connecting, such as “connect,” “interconnect,” and “bond,” unless specifically defined otherwise, may refer to situations where two structures are in direct contact, or may also refer to situations where two structures are not in direct contact, with other structures arranged between these two structures. Moreover, these terms related to connecting and joining may also include cases where both structures are movable, or both structures are fixed. Additionally, “coupled” or “connected” as used herein may refer to two or more components being in direct physical or electrical contact with each other, or indirect physical or electrical contact with each other, and may also refer to two or more components interacting or operating with each other.

Some embodiments of the present disclosure may be better understood in conjunction with the accompanying drawings, which are considered part of the description of the embodiments. It should be noted that the drawings of the embodiments are not necessarily drawn to scale with actual devices and components. In the drawings, the shapes and thicknesses of the embodiments may be exaggerated to clearly illustrate the features of the embodiments. Moreover, the structures and devices in the drawings are depicted schematically to clearly illustrate the features of the embodiments.

As used herein, the term “device” generally refers to an object comprising one or more transistors and/or one or more active and passive components connected in a predetermined manner to process signals.

Here, the terms “about,” “approximately,” and “roughly” generally indicate within 20% of a given value or range, preferably within 10%, and more preferably within 5%, or within 3%, or within 2%, or within 1%, or within 0.5%. The quantities given herein are approximate quantities, meaning that the meaning of “about,” “approximately,” or “roughly” may still be implicitly included even without specific mention of “about,” “approximately,” or “roughly”. The term “a range between a first value and a second value” means that the described range includes the first value, the second value, and other values between them. Furthermore, a certain error may exist between any two values or directions used for comparison. If the first value is equal to the second value, it implies that there may be an error of about 10%, or within 5%, or within 3%, or within 2%, or within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Certain terms are used in the specification and claims to refer to specific components. However, those of ordinary skill in the art will understand that the same components may be referred to by different terms. The specification and claims do not distinguish components based on the differences in their names, but rather based on differences in their functions. The term “comprising” used in the specification and claims is an open-ended term and should be interpreted as “including but not limited to.”

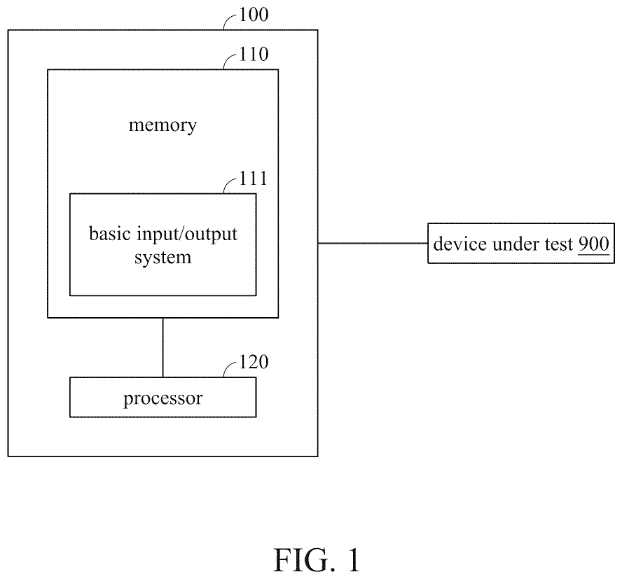

FIG. 1 is a block diagram of a memory overclocking device according to one embodiment of the present disclosure. As shown in the figure, the memory overclocking device 100 includes a memory 110 and a processor 120. The memory 110 stores a plurality of instructions and a basic input/output system (BIOS) 111. The memory 110 may be coupled to the processor 120. In some embodiments, the basic input/output system 111 may alternatively be stored and/or executed in other components within the memory overclocking device 100, but the present disclosure is not limited thereto.

For example, the basic input/output system 111 may be any type of basic input/output system, or other program languages, algorithms, software, firmware, or the like having similar functions, but the present disclosure is not limited thereto.

In some embodiments, the processor 120 may be a microprocessor (Micro-Processor Unit, MPU), a central processing unit (CPU), a graphics processing unit (GPU), a microcontroller unit (MCU), a server, or the like, but the present disclosure is not limited thereto.

In some embodiments, the memory 110 may be a random-access memory (RAM), a non-volatile random-access memory (NVRAM), a read-only memory (ROM), a cache memory (cache), a flash memory (flash), a memory card, a hard disk (e.g., cloud disk, network disk, or external disk), an optical disk, a universal serial bus (USB) flash drive, a database, or the like, but the present disclosure is not limited thereto.

In one embodiment, the processor 120 is configured to execute the following steps according to a plurality of instructions of the memory 110: performing an overclocking prediction for a device under test 900 according to an overclocking algorithm by the basic input/output system 111.

For example, the device under test 900 may be any generation or any type of double data rate (DDR) memory. The overclocking algorithm may be stored in the memory 110. The plurality of instructions of the memory 110 may be any type of program code, algorithm, software, or firmware, but the present disclosure is not limited thereto.

In some embodiments, the overclocking algorithm may be one of any type of artificial neural network (ANN) model, any type of big data algorithm, any type of machine learning algorithm, any type of artificial intelligence (AI) algorithm, or any type of Chat Generative Pre-trained Transformer (ChatGPT) algorithm, but the present disclosure is not limited thereto.

In one embodiment, the processor 120 is configured to execute the following steps according to the plurality of instructions of the memory 110: outputting an optimal overclocking result data according to the overclocking prediction by the basic input/output system 111.

Further, the processor 120 may perform DDR overclocking capability prediction through BIOS and AI computation to obtain a target frequency, i.e., the optimal overclocking result data, but the present disclosure is not limited thereto. For example, the original DDR frequency of a certain brand of DDR memory may be 5600 mega transfers per second (MT/s). By means of the overclocking algorithm of the present disclosure, the optimal overclocking result data may be obtained, and the optimal overclocking result data may be 7600 MT/s, but the present disclosure is not limited thereto.

In one embodiment, the processor 120 is configured to execute the following steps according to the plurality of instructions of the memory 110: outputting at least two compliance result data according to the optimal overclocking result data, a hardware data of the device under test 900, and a frequency threshold range data.

For example, the hardware data of the device under test 900 may include the dies, brand, characteristics, model, and the like of the double data rate (DDR) memory. The frequency threshold range data may represent a frequency range supported by the device under test 900. The at least two compliance result data may include information indicating that the computer does not experience a blue screen or crash during operation, but the present disclosure is not limited thereto.

Further, the processor 120 may, according to the optimal overclocking result data of the DDR memory (e.g., 7600 MT/s), die information, model information, and supported frequency information, obtain the first compliance result data (such as 7200 MT/s), the second compliance result data (such as 8000 MT/s), and the third compliance result data (such as 8200 MT/s), but the present disclosure is not limited thereto.

In some embodiments, the hardware data of the device under test 900 may include generation information of the processor 120 or processor-related information, for example, fifth-generation Double Data Rate Synchronous Dynamic Random Access Memory (DDR5), but the present disclosure is not limited thereto.

In some embodiments, the memory overclocking device 100 may be coupled to the plurality of DDR memories, and the memory overclocking device 100 may perform overclocking prediction for each of the plurality of DDR memories.

For example, each of the plurality of DDR memories (or each set thereof) may differ according to its die, brand, characteristics, and inherent hardware capabilities. Even DDR memories of the same model may have variations in capability, resulting in differences in achievable overclocking limits. Through AI computation, such differences may be taken into account to provide the user with optimal configuration results, and the overclocking limits may exceed the target frequencies achievable by the manufacturer's built-in XMP profile, but the present disclosure is not limited thereto.

In one embodiment, the optimal overclocking result data comprises an optimal frequency data, a vendor data of the device under test 900, at least one time data of the device under test, and an optimal voltage data.

For example, the optimal frequency data may be 7600 MT/s. The vendor data of the device under test may, for example, be SK Hynix, Micron, Samsung, or the like. At least one timing data of the device under test may include the timing data of the DDR memory (DDR timing). The optimal voltage data may be 1.4 volts (V), but the present disclosure is not limited thereto.

In one embodiment, the frequency threshold range data comprises 200 to 400 Megahertz (MHz).

For example, the frequency threshold range data may be the frequency difference between the at least two compliance result data (two or more compliance result data). For instance, when the optimal overclocking result data is 7600 MT/s, the at least two compliance result data may be 7400 MT/s, 7800 MT/s, and 8000 MT/s, but the present disclosure is not limited thereto.

In one embodiment, the processor 120 further executes the following steps according to the plurality of instructions of the memory 110: determining whether the optimal overclocking result data is an optimal result according to the overclocking algorithm, an initial setting data of the device under test 900, and the hardware data of the device under test 900; and when it is determined that the optimal overclocking result data is the optimal result, tagging a recommendation symbol on the optimal overclocking result data.

For example, the initial setting data of the device under test 900 may include the original frequency value of the DDR memory, the original timing data of the DDR memory, and the like. When the processor 120 determines that the optimal overclocking result data is the optimal result, the processor 120 may tag (or annotate) the optimal overclocking result data with the recommendation symbol. The recommendation symbol may be of any type, for example, a star, a triangle, an emoji, or a sticker, but the present disclosure is not limited thereto.

In some embodiments, the processor 120 may further determine whether the optimal overclocking result data is truly the optimal result based on information related to the device under test 900. If the result is not the optimal result, the DDR overclocking capability prediction is performed again to obtain a new target frequency, and the new target frequency is then verified to determine whether it is the optimal result, but the present disclosure is not limited thereto.

In one embodiment, the processor 120 further executes the following steps according to the plurality of instructions of the memory 110: determining whether the at least two compliance result data meet a product specification according to the overclocking algorithm and a hardware data of the device under test 900; and when it is determined that the at least two compliance result data meet the product specification, outputting the at least two compliance result data to an interface.

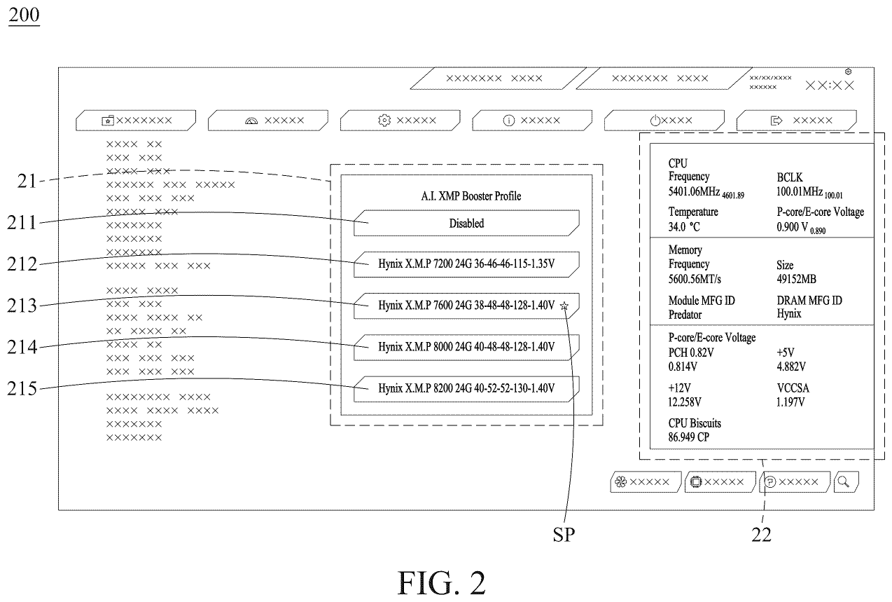

For example, the processor 120 may, via the overclocking algorithm, compare the hardware data of the device under test 900 and the at least two compliance result data to determine whether they comply with a product specification. The interface may be any display screen, monitor, or any type of operation interface, but the present disclosure is not limited thereto. In some embodiments, may directly compare the hardware data of the device under test 900 and the at least two compliance result data to verify whether they comply with a product specification, but the present disclosure is not limited thereto. In some embodiments, the processor 120 may output the at least two compliance result data to the interface 200 shown in FIG. 2 below, but the present disclosure is not limited thereto.

FIG. 2 is a schematic diagram of a usage scenario of a memory overclocking device according to one embodiment of the present disclosure. As shown in the figure, FIG. 2 may include the interface 200, the data 21, the data 22, a plurality of options 211 to 215, and a symbol SP.

For example, the interface 200 may be the user interface, the data 21 may be related to the initial setting data of the device under test 900 and/or the hardware data of the device under test 900, the data 22 may be related to the overclocking algorithm and/or the optimal overclocking result data, the plurality of options 211 to 215 may be related to the optimal overclocking result data and/or the at least two compliance result data, and the symbol SP may correspond to the recommendation symbol, but the present disclosure is not limited thereto.

In some embodiments, the data 21 may be a booster profile, the option 211 may be disable, the plurality of options 212, 214, and 215 may be compliance result data, and the option 213 may be the optimal overclocking result data, but the present disclosure is not limited thereto.

In some embodiments, the number of options corresponding to the data 21 may be more than five, and may be arbitrarily adjusted according to requirements, but the present disclosure is not limited thereto. In some embodiments, the content of the data 21 may be derived from a product specification or a hardware specification of the DDR memory.

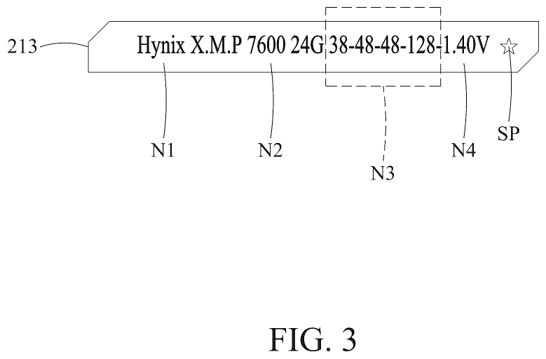

FIG. 3 is a schematic diagram of a usage scenario of a memory overclocking device according to one embodiment of the present disclosure. As shown in the figure, the option 213 may include a plurality of data N1 to N4 and a symbol SP.

For example, the option 213 of FIG. 3 may correspond to the option 213 of FIG. 2. The option 213 may be associated with the optimal overclocking result data. The plurality of data N1 to N4 may be associated with the hardware data of the device under test (DUT) 900, the optimal frequency data, the vendor data of the device under test 900, the at least one time data of the device under test 900, and the optimal voltage data, and the like, but the present disclosure is not limited thereto.

In some embodiments, the 38-48-48-128 in the data N3 can correspond in sequence to the following parameters: the first timing parameter (such as CAS (Column Address Strobe) Latency, tCL), the second timing parameter (such as RAS to CAS Delay Time, tRCD), the third timing parameter (such as Row Precharge Delay Time, tRP), and the fourth timing parameter (such as Active to Precharge Delay Time, tRAS), but the present disclosure is not limited thereto.

In addition, the content presentation logic of the plurality of options 212 to 215 in FIG. 2 may be similar to the content presentation logic of the option 213 in FIG. 3. For the sake of brevity in the specification, further details are omitted here.

Please refer to FIG. 1 to FIG. 3, in one embodiment, the processor 120 further executes the following steps according to the plurality of instructions of the memory 110: setting up an operation interface.

For example, the processor 120 may set up the operation interface on any display medium (such as a display device), and the operation interface may correspond to the interface 200 in FIG. 2, but the present disclosure is not limited thereto.

In this embodiment, the processor 120 further executes the following steps according to the plurality of instructions of the memory 110: displaying an initial setting data of the device under test 900, the hardware data of the device under test 900, the optimal overclocking result data, and the at least two compliance result data on operation interface.

For example, the data displayed in the operation interface may be similar to the data 21 and/or the data 22 shown in FIG. 2. The initial setting data of the device under test 900 and/or the hardware data of the device under test 900 may be similar to the data 22 shown in FIG. 2. The optimal overclocking result data may be similar to the option 213 shown in FIG. 2. The at least two compliance result data may correspond to the options 212, 214, and 215 shown in FIG. 2, but the present disclosure is not limited thereto.

In this embodiment, the processor 120 further executes the following steps according to the plurality of instructions of the memory 110: tagging a recommendation symbol on the optimal overclocking result data according to the overclocking algorithm, an initial setting data of the device under test 900, and the hardware data of the device under test 900.

For example, the recommendation symbol may correspond to the symbol SP shown in FIG. 2 or FIG. 3, but the present disclosure is not limited thereto.

In one embodiment, the processor 120 further executes the following steps according to the plurality of instructions of the memory 110: determining whether to perform an overclocking prediction training by the basic input/output system 111 according to an initial setting data of the device under test 900.

For example, the initial setting data of the device under test 900 may include the DDR replacement data or the DDR timing modification data, but the present disclosure is not limited thereto. In some embodiments, the processor 120 determines whether to perform overclocking prediction training by the BIOS according to situations such as a freshly updated BIOS, a DDR replacement, or changes in DDR timing, but the present disclosure is not limited thereto. In some embodiments, the initial setting data of the device under test 900 may include at least one DDR timing data, but the present disclosure is not limited thereto.

In this embodiment, the processor 120 further executes the following steps according to the plurality of instructions of the memory 110: when it is determined to perform the overclocking prediction training, recording a result of the overclocking prediction training to the memory 110 by the basic input/output system.

For example, when it is determined to perform overclocking prediction training, the BIOS may record the results of the overclocking prediction training into the memory 110, such as a Non-Volatile Random Access Memory (NVRAM), but the present disclosure is not limited thereto.

In some embodiments, when the processor 120 determines to perform overclocking prediction training, the BIOS may calculate all the DDR timings, but the present disclosure is not limited thereto. In some embodiments, when the processor 120 determines to perform the overclocking prediction training, the processor 120 or the BIOS may record the current DDR status or related data (such as the memory chip data, the vendor data, the capacity data, the voltage data, the various timing data, and the signal margin data during the training process) into the memory 110, but the present disclosure is not limited thereto.

In this embodiment, the processor 120 further executes the following steps according to the plurality of instructions of the memory 110: updating the overclocking algorithm with the result of the overclocking prediction training by the basic input/output system 111.

For example, the BIOS may further update the overclocking algorithm with the results of the overclocking prediction training, allowing the user to perform overclocking prediction more accurately when using the overclocking algorithm, but the present disclosure is not limited thereto.

In one embodiment, the initial setting data comprises at least one of an updated basic input/output system data, a replacement data of the device under test, and a modified time data of the device under test.

In some embodiments, the overclocking prediction training may be performed before the Operating System (OS) is started, but the present disclosure is not limited thereto. In some embodiments, when the processor 120 determines not to perform overclocking prediction training, the Operating System may be started directly, but the present disclosure is not limited thereto.

In one embodiment, the device under test 900 and the memory 110 are different from each other; wherein the device under test 900 comprises a dynamic random access memory.

For example, the memory 110 may include the NVRAM, the device under test 900 may include the DDR memory, but the present disclosure is not limited thereto.

In one embodiment, the memory overclocking device 100 includes a motherboard.

For example, the memory overclocking device 100 may include the motherboard (mainboard), the system board, or the logic board, but the present disclosure is not limited thereto.

In some embodiments, device under test 900 may be disposed within the memory overclocking device 100, but the present disclosure is not limited thereto. In some embodiments, the device under test 900 may be the same as the memory 110, but the present disclosure is not limited thereto. In some embodiments, the basic input/output system 111 may be disposed (or stored) at any location within the memory overclocking device 100, but the present disclosure is not limited thereto. In some embodiments, the basic input/output system 111 may be disposed (or stored) at any location outside the memory overclocking device 100, but the present disclosure is not limited thereto.

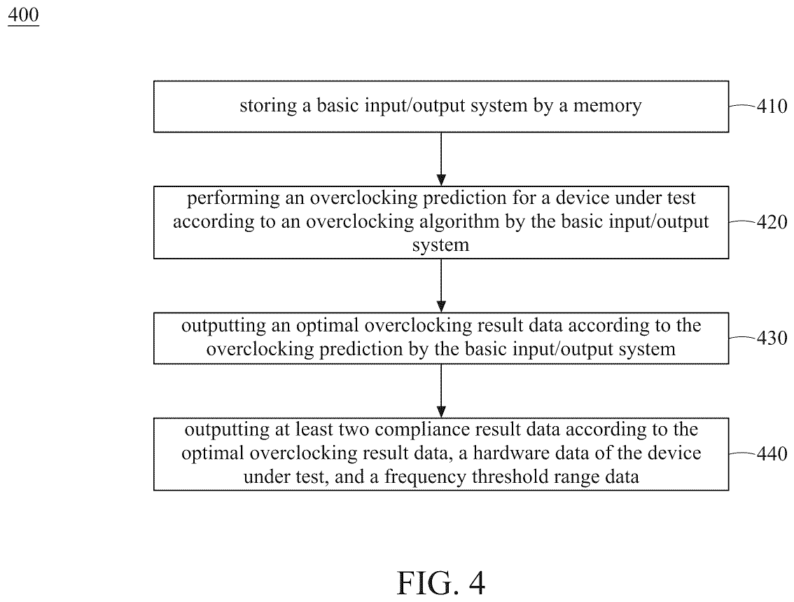

FIG. 4 is a flowchart of steps of a memory overclocking method according to one embodiment of the present disclosure. As shown in the figure, the memory overclocking method 400 includes a plurality of steps 410, 420, 430, and 440. Please refer to FIG. 1 to FIG. 4. Detailed step-by-step operations are described below.

In the step 410, storing a basic input/output system by a memory.

In one embodiment, the processor 120 may store the basic input/output system 111 by the memory 110.

In the step 420, performing an overclocking prediction for a device under test according to an overclocking algorithm by the basic input/output system.

In one embodiment, the processor 120 may perform the overclocking prediction for the device under test 900 according to the overclocking algorithm by the basic input/output system 111.

In the step 430, outputting an optimal overclocking result data according to the overclocking prediction by the basic input/output system.

In one embodiment, the processor 120 may output the optimal overclocking result data according to the overclocking prediction by the basic input/output system 111.

In the step 440, outputting at least two compliance result data according to the optimal overclocking result data, a hardware data of the device under test, and a frequency threshold range data.

In one embodiment, the processor 120 may output the at least two compliance result data according to the optimal overclocking result data, the hardware data of the device under test 900, and the frequency threshold range data.

For example, the operations of the memory overclocking method 400 shown in FIG. 4 may be similar to the operations of the memory overclocking device 100 shown in FIG. 1. For brevity of the specification, further description is omitted here.

In one embodiment, the optimal overclocking result data comprises an optimal frequency data, a vendor data of the device under test 900, at least one time data of the device under test 900, and an optimal voltage data.

In one embodiment, the frequency threshold range data includes 200 to 400 MHz.

In one embodiment, the memory overclocking method 400 further includes the following steps: determining whether the optimal overclocking result data is an optimal result according to the overclocking algorithm, an initial setting data of the device under test 900, and the hardware data of the device under test 900; and when it is determined that the optimal overclocking result data is the optimal result, tagging a recommendation symbol on the optimal overclocking result data.

In one embodiment, the memory overclocking method 400 further includes the following steps: determining whether the at least two compliance result data meet a product specification according to the overclocking algorithm and a hardware data of the device under test 900; and when it is determined that the at least two compliance result data meet the product specification, outputting the at least two compliance result data to an interface.

In one embodiment, the memory overclocking method 400 further includes the following steps: setting up an operation interface; displaying an initial setting data of the device under test 900, the hardware data of the device under test 900, the optimal overclocking result data, and the at least two compliance result data on operation interface; and tagging a recommendation symbol on the optimal overclocking result data according to the overclocking algorithm, an initial setting data of the device under test 900, and the hardware data of the device under test 900.

In one embodiment, the memory overclocking method 400 further includes the following steps: determining whether to perform an overclocking prediction training by the basic input/output system 111 according to an initial setting data of the device under test 900; when it is determined to perform the overclocking prediction training, recording a result of the overclocking prediction training to the memory 110 by the basic input/output system 111; and updating the overclocking algorithm with the result of the overclocking prediction training by the basic input/output system 111.

In one embodiment, the initial setting data comprises at least one of an updated basic input/output system data, a replacement data of the device under test 900, and a modified time data of the device under test 900.

In one embodiment, the device under test 900 and the memory 110 are different from each other, and the device under test 900 includes a dynamic random access memory.

In one embodiment, the memory overclocking method 400 is executed by a motherboard.

In some embodiments, the memory overclocking method 400 may be implemented via the memory overclocking device 100, but the present disclosure is not limited thereto. In some embodiments, the memory overclocking method 400 may be implemented via a non-transitory computer-readable storage medium, but the present disclosure is not limited thereto. In some embodiments, the memory overclocking method 400 may be implemented by other systems or servers, but the present disclosure is not limited thereto.

Therefore, according to the technical content of the present disclosure, the memory overclocking device and memory overclocking method shown in the embodiment of the present disclosure can achieve stable memory overclocking through a corresponding algorithm, even without requiring the user to possess a professional technical background in Double Data Rate (DDR) memory overclocking.

It should also be understood that ordinal terms such as “first” and “second” used in the specification and the claims are merely for distinguishing between similar elements, and do not imply any temporal or sequential order, nor do they indicate any order of manufacturing or arrangement between the elements. The use of such ordinals is intended solely to clarify the distinction between elements of similar designation. The terminology used in the claims may differ from that in the specification; for example, an element referred to as the “first element” in the specification may be referred to as the “second element” in the claims.

The scope of protection described in this disclosure is not limited to the processes, machines, manufacture, compositions of matter, devices, methods, or steps of the specific embodiments described in the specification. Any person of ordinary skill in the art can understand from the disclosure that any currently known or future-developed processes, machines, manufacture, compositions of matter, devices, methods, or steps that perform substantially the same function or achieve substantially the same result as those in the disclosed embodiments may be utilized in accordance with this disclosure. Therefore, the scope of protection of this disclosure includes such processes, machines, manufacture, compositions of matter, devices, methods, and steps. Any embodiment or claim of this disclosure need not achieve all of the objectives, advantages, and/or features disclosed herein.

Several embodiments have been outlined above to facilitate the understanding of the disclosed embodiments by those skilled in the art. It should be understood by those skilled in the art that they may design or modify other processes and structures based on the disclosed embodiments to achieve the same objectives and/or advantages as those described herein. It should also be understood by those skilled in the art that such equivalent processes and structures do not depart from the spirit and scope of the present disclosure, and that various modifications, substitutions, and alterations may be made without departing from the spirit and scope of the present disclosure.

Although the specific embodiments of the present invention are disclosed in the foregoing description, they are not intended to limit the invention. Those of ordinary skill in the art may make various modifications and variations without departing from the principles and spirit of the invention. Accordingly, the scope of the invention is defined by the appended claims.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A memory overclocking device, comprising:
a memory, configured to store a plurality of instructions and a basic input/output system; and
a processor, configured to execute following steps according to the plurality of instructions of the memory:
performing an overclocking prediction for a device under test according to an overclocking algorithm by the basic input/output system;
outputting an optimal overclocking result data according to the overclocking prediction by the basic input/output system; and
outputting at least two compliance result data according to the optimal overclocking result data, a hardware data of the device under test, and a frequency threshold range data.

2. The memory overclocking device as claimed in claim 1, wherein
the optimal overclocking result data comprises an optimal frequency data, a vendor data of the device under test, at least one time data of the device under test, and an optimal voltage data.

3. The memory overclocking device as claimed in claim 1, wherein
the frequency threshold range data comprises 200 to 400 MHz.

4. The memory overclocking device as claimed in claim 1, wherein
the processor further executes the following steps according to the plurality of instructions of the memory:
determining whether the optimal overclocking result data is an optimal result according to the overclocking algorithm, an initial setting data of the device under test, and the hardware data of the device under test; and
when it is determined that the optimal overclocking result data is the optimal result, tagging a recommendation symbol on the optimal overclocking result data.

5. The memory overclocking device as claimed in claim 4, wherein
the processor further executes the following steps according to the plurality of instructions of the memory:
determining whether the at least two compliance result data meet a product specification according to the overclocking algorithm and the hardware data of the device under test; and
when it is determined that the at least two compliance result data meet the product specification, outputting the at least two compliance result data to an interface.

6. The memory overclocking device as claimed in claim 1, wherein
the processor further executes the following steps according to the plurality of instructions of the memory:
setting up an operation interface;
displaying an initial setting data of the device under test, the hardware data of the device under test, the optimal overclocking result data, and the at least two compliance result data on operation interface; and
tagging a recommendation symbol on the optimal overclocking result data according to the overclocking algorithm, the initial setting data of the device under test, and the hardware data of the device under test.

7. The memory overclocking device as claimed in claim 1, wherein
the processor further executes the following steps according to the plurality of instructions of the memory:
determining whether to perform an overclocking prediction training according to an initial setting data of the device under test;
when it is determined to perform the overclocking prediction training, recording a result of the overclocking prediction training to the memory by the basic input/output system; and
updating the overclocking algorithm with the result of the overclocking prediction training by the basic input/output system.

8. The memory overclocking device as claimed in claim 7, wherein
the initial setting data comprises at least one of an updated basic input/output system data, a replacement data of the device under test, and a modified time data of the device under test.

9. The memory overclocking device as claimed in claim 1, wherein
the device under test and the memory are different from each other;
wherein the device under test comprises a dynamic random access memory.

10. The memory overclocking device as claimed in claim 1, wherein
the memory overclocking device comprises a motherboard.

11. A memory overclocking method, comprising:
storing a basic input/output system by a memory;
performing an overclocking prediction for a device under test according to an overclocking algorithm by the basic input/output system;
outputting an optimal overclocking result data according to the overclocking prediction by the basic input/output system; and
outputting at least two compliance result data according to the optimal overclocking result data, a hardware data of the device under test, and a frequency threshold range data.

12. The memory overclocking method as claimed in claim 11, wherein
the optimal overclocking result data comprises an optimal frequency data, a vendor data of the device under test, at least one time data of the device under test, and an optimal voltage data.

13. The memory overclocking method as claimed in claim 11, wherein
the frequency threshold range data comprises 200 to 400 MHz.

14. The memory overclocking method as claimed in claim 11, further comprising:
determining whether the optimal overclocking result data is an optimal result according to the overclocking algorithm, an initial setting data of the device under test, and the hardware data of the device under test; and
when it is determined that the optimal overclocking result data is the optimal result, tagging a recommendation symbol on the optimal overclocking result data.

15. The memory overclocking method as claimed in claim 14, further comprising:
determining whether the at least two compliance result data meet a product specification according to the overclocking algorithm and the hardware data of the device under test; and
when it is determined that the at least two compliance result data meet the product specification, outputting the at least two compliance result data to an interface.

16. The memory overclocking method as claimed in claim 11, further comprising:
setting up an operation interface;
displaying an initial setting data of the device under test, the hardware data of the device under test, the optimal overclocking result data, and the at least two compliance result data on operation interface; and
tagging a recommendation symbol on the optimal overclocking result data according to the overclocking algorithm, the initial setting data of the device under test, and the hardware data of the device under test.

17. The memory overclocking method as claimed in claim 11, further comprising:
determining whether to perform an overclocking prediction training according to an initial setting data of the device under test;
when it is determined to perform the overclocking prediction training, recording a result of the overclocking prediction training to the memory by the basic input/output system; and
updating the overclocking algorithm with the result of the overclocking prediction training by the basic input/output system.

18. The memory overclocking method as claimed in claim 17, wherein
the initial setting data comprises at least one of an updated basic input/output system data, a replacement data of the device under test, and a modified time data of the device under test.

19. The memory overclocking method as claimed in claim 11, wherein
the device under test and the memory are different from each other;
wherein the device under test comprises a dynamic random access memory.

20. The memory overclocking method as claimed in claim 11, wherein
the memory overclocking method is executed by a motherboard.
